(19) United States
(12) Patent Application Publication
(10) Pub. No.: US 2006/0231032 A1
(43) Pub. Date: Oct. 19, 2006

(54) Film-forming method and apparatus using plasma CVD

(76) Inventors: Seishi Murakami, Nirasaki-Shi (JP); Kunihiro Tada, Nirasaki-Shi (JP)

Correspondence Address: SMITH, GAMBRELL & RUSSELL, 1850 M STREET, N.W., SUITE 800, WASHINGTON, DC, 20036, US

(21) Appl. No.: 11/320,535

(22) Filed: Dec. 29, 2005

Related U.S. Application Data
(63) Continuation-in-part of application No. PCT/JP04/09332, filed on Jul. 1, 2004.

(30) Foreign Application Priority Data
Jul. 1, 2003 (JP) 2003-270044

(51) Int. Cl. C23C 16/00

(52) U.S. Cl. 118/723 R; 700/121

(57) ABSTRACT

The object of the present invention is to provide a plasma chemical vapor deposition method and apparatus capable of preventing local electric discharge at the peripheral portion of the susceptor. Prior to the film formation, a gas is supplied into an evacuated chamber, and a substrate is supported on substrate support pins, which is arranged in the susceptor and are in their elevated position, so that the substrate is preheated; thereafter the supply of the gas is stopped, the chamber is evacuated, and the substrate support pins are lowered so that the substrate is placed on the susceptor; and thereafter a gas is supplied into the chamber and the substrate is further preheated. Thereafter, plasma is generated in the chamber, and the film-forming gas is supplied into the chamber, to form a film on the substrate.

### TECHNICAL FIELD

The present invention relates to a method and apparatus for forming a thin film such as a Ti film by plasma CVD.

### BACKGROUND ART

Semiconductor devices employ a multilayer wiring structure to meet the recent demand for high integration and high density. In order to form electrical connections between layers in a semiconductor device, a technique of filling a metal into the contact holes for connecting between the semiconductor substrate and the overlying wiring layers and into the via holes for connecting between upper and lower wiring layers is important.

Aluminum (Al) or tungsten (W) or an alloy thereof is typically used to fill contact holes and via holes. To form a contact between such a metal or alloy and the underlying Si substrate or poly-Si layer, a Ti film is formed on the inner surfaces of these contact holes and via holes, and subsequently a TiN film as a barrier layer is formed before filling the contact holes and via holes.

Recently, chemical vapor deposition (CVD), which can form films of good quality, has been used to form the Ti and TiN films. The Ti film-forming process uses TiCl₄ (titanium tetrachloride) and H₂ (hydrogen) as film-forming gases; heats a semiconductor wafer (i.e., substrate) by a heater; generates plasma originated from the film-forming gases; and reacts TiCl₄ with H_{2.}

A susceptor, which is used for supporting the semiconductor wafer during the Ti film formation, is formed of an insulating material such as a ceramic, and incorporates an electrically conductive heating element and an electrode to which a radio frequency power is applied.

Recently, semiconductor wafers (hereinafter referred to simply as “wafer(s)”) have been increased in size from 200 mm to 300 mm. Therefore, when a wafer is placed on a susceptor, slippage between the wafer and the susceptor is likely to occur due to a gas present between the top surface of the susceptor and the back surface of the wafer. Furthermore, heat spots may appear on the surface of the wafer heated by the heater embedded in the susceptor, leading to nonuniform temperature distribution across the wafer. This might result in degradation in the in-plane uniformity of the film thickness.

JP 2002-124367A discloses a susceptor provided on the surface thereof with a number of embosses (or protrusions) in order to overcome the above problem.

However, when such a susceptor having embosses on its surface is used to form a Ti film by plasma CVD (plasma-enhanced CVD) through application of a radio frequency electric field, electric discharge may occur between the peripheral portion of the susceptor and the wafer, resulting in breakage of the peripheral portion of the susceptor.

### DISCLOSURE OF INVENTION

The present invention has been made in view of the above problems. It is, therefore, an object of the present invention to provide a plasma CVD film-forming method and apparatus capable of preventing local electric discharge on the peripheral portion of the susceptor.

The present inventors have studied the electric discharge on the peripheral portion of a susceptor with an embossed surface during a plasma CVD process, and found that electric discharge occurs between the back surface of the wafer and some embosses due to warpage of the peripheral portion of the wafer. It is considered that, as an electric field tends to concentrate on the embosses (or protrusions) of the susceptor surface, electric discharge occurs predominantly on them if the peripheral portion of the wafer warps (even if slightly warps) so that a gap is formed between the wafer and the susceptor.

Further, according to Paschen's Law, sparkover voltage Vs is a function of the product pd of gas pressure p and distance d. The sparkover voltage Vs is minimized at a particular value of pd. Therefore, if the pressure p is assumed to be constant, an electric discharge occurs even at a low voltage when the amount of warpage of the wafer has reached a certain level.

In order to solve the above problems, the present invention provides, based on the above knowledge, means for preventing a substrate from warping and/or means for preventing electric discharge even if the substrate warps.

Specifically, the present invention provides a chemical vapor deposition method that generates a plasma by using a radio frequency electric field produced in a process chamber, and forms a thin film on a substrate, which is placed on a susceptor and is heated through the susceptor by a heating element arranged in the susceptor, wherein the substrate is preheated before starting formation of the thin film, with the substrate being held by substrate support pins which are arranged in the susceptor and are in their raised positions.

The present invention also provides a chemical vapor deposition method that generates a plasma by using a radio frequency electric field produced in a process chamber, and forms a thin film on a substrate, which is placed on a susceptor and is heated through the susceptor by a heating element arranged in the susceptor, the method including the steps of: transferring the substrate into the process chamber and raising substrate support pins arranged in the susceptor, thereby supporting the substrate on the substrate support pins; supplying a gas into the process chamber, which is being evacuated, and heating the susceptor by the heating element, thereby performing first preheating of the substrate while the substrate is being supported on the substrate support pins; stopping supplying the gas into the process chamber while the process chamber is being evacuated, and lowering the substrate support pins to place the substrate on the susceptor; supplying a gas into the process chamber while the substrate is placed on the susceptor, thereby performing second preheating of the substrate; generating a plasma in the process chamber; and

supplying a film-forming gas into the process chamber to form a thin film on the substrate.

According to the present invention, the substrate is preheated as it is supported on raised substrate support pins, thereby preventing the substrate from being rapidly heated. This allows warpage of the substrate to be eliminated or significantly reduced. As a result, it is possible to prevent local electric discharge on the peripheral portion of the surface of the susceptor even when the susceptor is placed in a radio frequency electric field.

If the preheating is performed while supplying a gas into the process chamber, substrate heating efficiency is improved, reducing the preheating time.

When the substrate is preheated as it is supported on the susceptor, the gas pressure in the process chamber is preferably gradually increased so as to prevent a rapid increase in the gas pressure in the chamber. This leads to a reduction in the stress induced in the substrate and hence a further reduction in the possibility of substrate warpage.

When the radio frequency electric field is produced to generate the plasma, the strength of the radio frequency electric field may be gradually increased to reduce the possibility of electric discharge.

Preferably, at least the peripheral portion of the surface of the susceptor is not provided with embosses (such as that employed in the foregoing conventional technique), to which an electric field tends to concentrate and at which an electric discharge may start. Preferably, the susceptor is formed such that: at least a surface of a peripheral portion of a substrate mounting region of the susceptor is formed to be flat; and the surface of the peripheral portion is in surface contact with the portion of a surface of the substrate opposing the peripheral portion when the substrate is placed on the susceptor. This arrangement prevents electric discharge even when the sparkover voltage Vs is reduced due to warpage of the substrate.

The present invention further provides a plasma chemical vapor deposition apparatus including: a process chamber that accommodates a substrate to be processed; a susceptor that supports the substrate thereon, the susceptor having a heating element therein; a gas supply mechanism that supplies at least a film-forming gas into the process chamber; and plasma generating means for producing a radio-frequency electric field in said process chamber to generate a plasma; wherein at least a surface of a peripheral portion of a substrate mounting region of the susceptor is formed to be flat, whereby the surface of the peripheral portion is in surface contact with a portion of a surface of the substrate opposing the peripheral portion when the substrate is placed on said susceptor.

### BRIEF DESCRIPTION OF THE DRAWINGS

FIG. 1 is a schematic diagram showing the configuration of a multi-chamber film-forming system including Ti film-forming apparatuses for performing a film-forming method according to the present invention.

FIG. 2 is a cross-sectional view of a contact-hole portion of a semiconductor device employing a Ti film as its contact layer.

FIG. 3 is a cross-sectional view of a Ti film-forming apparatus for performing a plasma CVD film-forming method according to the present invention.

FIG. 4 is a cross-sectional view of a susceptor in another embodiment.

FIG. 5 is a cross-sectional view of a susceptor in another embodiment.

FIG. 6 is a cross-sectional view of a susceptor in another embodiment.

FIG. 7 is a flowchart illustrating process steps for forming a Ti film in one embodiment.

FIG. 8 shows schematic diagrams showing conditions of the interior of a chamber in each major process step.

FIG. 9 is a schematic diagram illustrating the mechanism of generation of an electric discharge in a conventional Ti film-forming apparatus.

FIG. 10 is a flowchart illustrating a part of process steps for forming a Ti film in another embodiment.

FIG. 11 is a graph showing the change in gas flow rates and gas pressure with time from a first preheating step to a second preheating step, in an experiment performed to determine the advantageous effects of a film-forming method of the present invention.

FIG. 12 is a block diagram schematically showing the structure of a control unit (control computer).

### BEST MODE FOR CARRYING OUT THE INVENTION

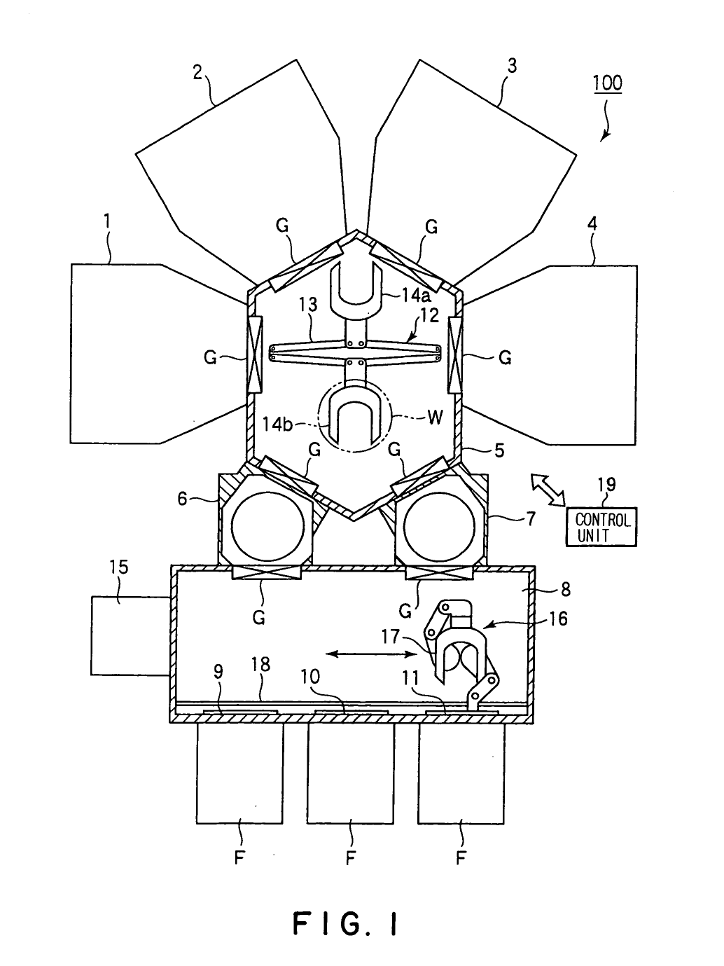

Preferred embodiments of the present invention will now be specifically described with reference to the accompanying drawings. FIG. 1 is a schematic diagram showing the configuration of a multi-chamber, film-forming system including Ti film-forming apparatuses for performing a film-forming method according to the present invention.

As shown in FIG. 1, a film-forming system 100 includes four film-forming apparatuses: Ti film-forming apparatuses 1 and 2 for forming a Ti film by plasma CVD; and TiN film-forming apparatuses 3 and 4 for forming a TiN film by thermal CVD. The film-forming apparatuses 1, 2, 3, and 4 are respectively provided on four sides of a wafer transfer chamber 5 having a hexagonal cross section. Load-lock chambers 6 and 7 are provided on the remaining two sides of the wafer transfer chamber 5. A wafer carrying-in-and-out chamber 8 is provided on the sides of the load-lock chambers 6 and 7 opposite to the wafer transfer chamber 5. Three ports 9, 10, and 11 are provided on the side of the wafer carrying-in-and-out chamber 8 opposite to the load-lock chambers 6 and 7. A FOUP capable of accommodating wafers W can be attached to each port.

The Ti film-forming apparatuses 1 and 2, the TiN film-forming apparatuses 3 and 4, and the load-lock chambers 6 and 7 are connected to respective sides of the wafer transfer chamber 5 through respective gate valves G, as shown in FIG. 1. These apparatuses and chambers are communicated with the wafer transfer chamber 5 when their respective gate valves G are opened; they are separated from the wafer transfer chamber 5 when these gate valves are closed. The load-lock chambers 6 and 7 are also connected to the wafer carrying-in-and-out chamber 8 through respective gate valves G. The load-lock chambers 6 and 7 are communicated with the wafer carrying-in-and-out chamber 8 when these gate valves are opened; they are separated from the wafer carrying-in-and-out chamber 8 when these gate valves are closed.

The wafer transfer chamber 5A is provided therein with a wafer transfer device 12 to transfer a wafer W to be processed to and from the Ti film-forming apparatuses 1 and 2, the TiN film-forming apparatuses 3 and 4, and the load-lock chambers 6 and 7. The wafer transfer device 12 is disposed approximately at the center of the wafer transfer chamber 5, and includes a rotatable-and-retractable part 13 which is provided on its tips with two blades 14a and 14b each for holding a wafer W. The blades 14a and 14b are attached to the rotatable-and-retractable part 13 such that they face in opposite directions. The blades 14a and 14b can be projected and retracted independently and simultaneously. The interior of the wafer transfer chamber 5 can be maintained at a predetermined degree of vacuum.

A HEPA filter (not shown) is provided on the ceiling portion of the wafer carrying-in-and-out chamber 8. Clean air passed through the HEPA filter supplied into the wafer carrying-in-and-out chamber 8 flows downward therein, which allows a wafer W to be transferred into and from the wafer carrying-in-and-out chamber 8 of a clean-air atmosphere of atmospheric pressure. A shutter (not shown) is provided on each of the three ports 9, 10, and 11, each for holding a FOUP, of the wafer carrying-in-and-out chamber 8. When a FOUP F accommodating wafers W or an empty FOUP F is attached to the port, the shutter is opened so that the interior of the FOUP is communicated with the wafer carrying-in-and-out chamber 8 while preventing ambient-air entry. An alignment chamber 15, in which a wafer W is aligned, is provided on a side of the wafer carrying-in-and-out chamber 8.

A wafer transfer device 16 is arranged in the wafer carrying-in-and-out chamber 8 to transfer a wafer W to and from the FOUP F and the load-lock chambers 6 and 7. The wafer transfer device 16 has an articulated structure and can be moved on a rail 18 in the direction in which the FOUPs F are arrayed. The wafer transfer device 16 transfers a wafer W while holding it on the hand 17 provided at the tip of the an articulated structure.

A control unit 19 controls the operation of the entire system, such as the operations of the wafer transfer devices 12 and 16, etc.

In the foregoing film-forming system 100, first, the wafer transfer device 16, which is arranged in the wafer carrying-in-and-out chamber 8 providing a clean-air atmosphere of atmospheric pressure therein, removes a wafer W from one of the FOUPs and transfers it to the alignment chamber 15, in which the wafer W is aligned. Thereafter, the wafer W is transferred to either the load-lock chamber 6 or 7; after the load-lock chamber is evacuated, the wafer transfer device 12 in the wafer transfer chamber 5 transfers the wafer W from the load-lock chamber to the Ti film-forming apparatus 1 or 2; and the wafer is subjected to a Ti film-forming process. Thereafter, the wafer W having been subjected to the Ti film-forming process is subsequently loaded into the TiN film-forming apparatus 3 or 4, in which a TiN film is formed on the wafer W. Thereafter, the wafer transfer device 12 transfers the wafer W having been subjected to the film-forming processes to the load-lock chamber 6 or 7. Then, after the load-lock chamber is returned to atmospheric pressure, the wafer transfer device 16 in the wafer carrying-in-and-out chamber 8 removes the wafer W from the load-lock chamber and returns it to one of the FOUPs F. The above operations are performed repeatedly to wafers W of one process lot, completing a set of film-forming processes.

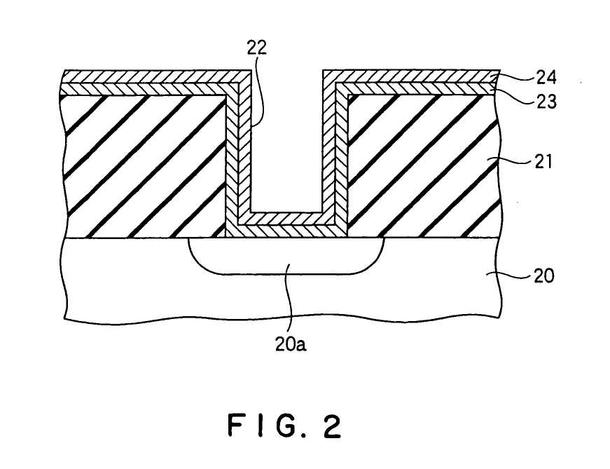

As shown in FIG. 2, a Ti film 23 serving as a contact layer and a TiN film 24 serving as a barrier layer may be formed in a contact hole 21, which is formed in an interlayer insulating film 21 and reaches an impurity diffusion region 20a, through the above film-forming processes. After the Ti film 23 and TiN film 24 are formed, an Al or W film, etc. are formed to fill the contact hole 22 and form wiring layers.

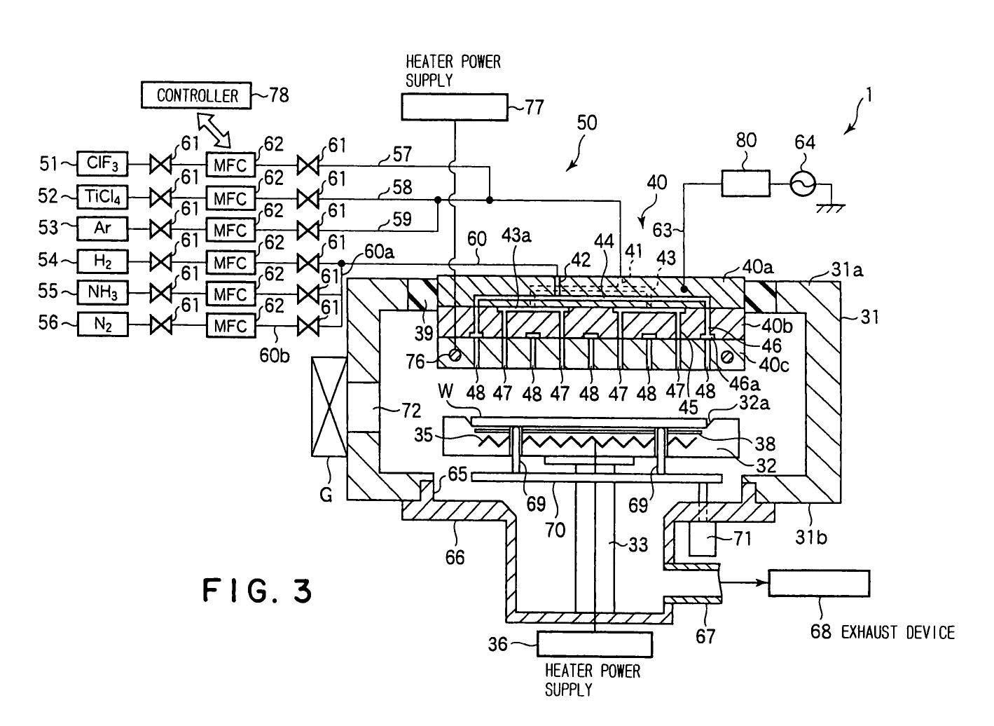

The Ti film-forming apparatus 1 that embodies the present invention will be described. The Ti film-forming apparatus 2 has the same configuration as the Ti film-forming apparatus 1, as described above. FIG. 3 is a cross-sectional view of a Ti film-forming apparatus for performing a plasma CVD film-forming method according to the present invention. The Ti film-forming apparatus 1 includes an airtight chamber 31 having a substantially cylindrical shape, in which a susceptor 32 for holding the wafer W (i.e., process object) in a horizontal posture is supported on a cylindrical support member 33 provided at the lower center portion of the chamber 31.

The susceptor 32 is formed of a ceramic material such as AIN, and has a seat recess portion 32a formed in its surface to receive the wafer W. The wafer W is guided by the tapered portion formed at the periphery of the seat recess portion 32a to be positioned with respect to the susceptor 32. Embedded in the susceptor 32 is a heater 35, which receives electric power from a heater power supply 36 to heat the wafer W (i.e., substrate to be processed) up to a predetermined temperature. Embedded also in the susceptor 32 is an electrode 38, which is located above the heater 35 and acts as a lower electrode. The surface of the susceptor 32 have no embosses, at which an electric discharge is likely to start when a radio-frequency electric field for generating plasma is produced in the chamber 31.

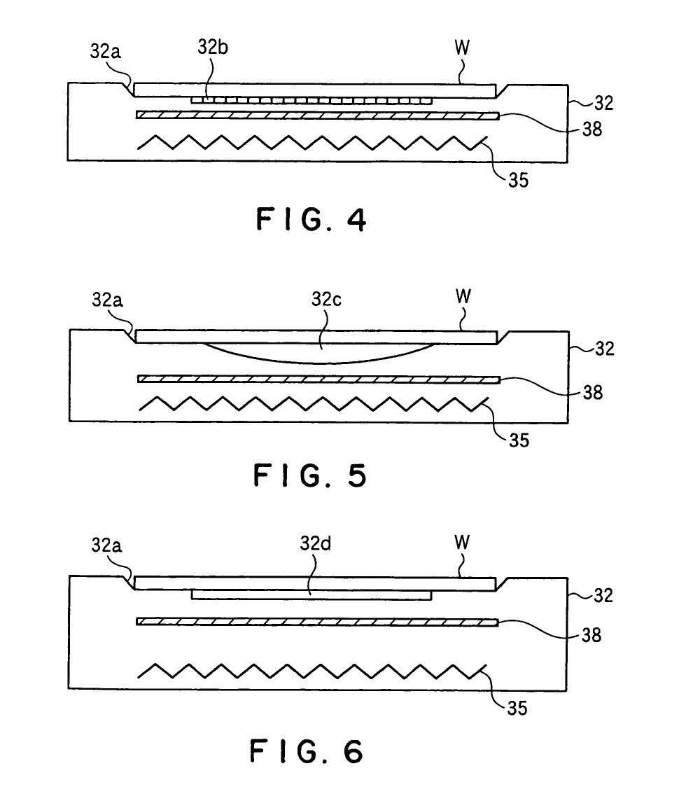

However, as electric discharge occurs only on the peripheral portion of the susceptor 32, the other portions of the surface of the susceptor 32 may be embossed. More specifically, it is sufficient that the annular region of the surface of the susceptor 32, which extends from the circumference of the circular wafer mounting region (in the illustrated embodiment, the seat recess portion 32a) to positions radially inwardly remote from the circumference by an predetermined distance (preferably, at least 10 mm), is not embossed. The annular region is preferably formed to be flat such that a portion of the back surface of the wafer W facing the annular region is substantially in surface contact with the annular region. FIG. 4 shows an example of such a susceptor 32. In the susceptor shown in FIG. 4, many embosses (or protrusions) 32b are formed at intervals over the portion of the surface of the substrate mounting region other than the peripheral portion. Each emboss 32b comprises a small cylindrical protrusion formed on the surface of the susceptor 32. The embosses 32b provide the susceptor 32 with capabilities to prevent slippage of the wafer W and prevent appearance of heat spots to some degree. In the case of the susceptor shown in FIG. 4, the center portion of the wafer W is supported on the top faces of the embosses 32b, while the peripheral portion of the wafer W is supported on the annular region of the surface of the susceptor. In the susceptor shown in FIG. 4, the height of each emboss 32b is preferably not less than 10 μm, and the diameter of each emboss 32b may be 3 μm. The sucface of the annular region inevitably has some irregularities due to manufacturing tolerances. The surface roughness (Ra) value of the annular region may be smaller than the height of the embosses 32b, preferably Ra≦6.3.

Since the temperature of the center portion of the wafer W tends to raise higher, a susceptor, which is provided at the center portion thereof with a concave portion 32c having a curved bottom surface shown in FIG. 5 or a concave portion 32d having a flat bottom surface shown in FIG. 6, may be used in order to reduce the thermal stress induced in the wafer W.

A shower head 40 is attached to a ceiling wall 31a of the chamber 31 through an insulating member 39. The shower head 40 includes an upper block 40a, a middle block 40b and a lower block 40c. A ring-shaped heater 76 is embedded in the peripheral portion of the lower block 40c. The heater 76 receives power from a heater power supply 77, whereby the heater 76 is capable of heating the shower head 40 up to a predetermined temperature.

Discharge holes 47 and discharge holes 48 are alternately formed in the lower block 40c to discharge a gas therefrom. A first gas introduction port 41 and a second gas introduction port 42 are formed in the upper surface of the upper block 40a. A number of gas passages 43 branch off from the first gas introduction port 41 in the upper block 40a. Gas passages 45 are formed in the middle block 40b. The gas passages 43 are communicated with the gas passages 45 through a plurality of grooves 43, into which the gas is introduced to be is diffused therein. The gas passages 45 are communicated with the discharge holes 47 in the lower block 40c. A number of gas passages 44 branch off from the second gas introduction port 42 in the upper block 40a. Gas passages 46 are formed in the middle block 40b. The gas passages 44 are communicated with the gas passages 46. Formed in the lower surface of the middle block 40b are plural grooves 46a, which are connected to the gas passages 46 and in which the gas introduced through the gas passages 46 is diffused. The grooves 46a are communicated with the discharge holes 48 in the lower block 40c. The first gas introduction port 41 and the second gas introduction port 42 are connected to gas lines 58 and 60, respectively, of a gas supply mechanism 50 (described later).

The gas supply mechanism 50 includes: a ClF₃ gas supply source 51 for supplying ClF₃ gas as a cleaning gas; a TiCI₄ gas supply source 52 for supplying TiCl₄ gas as a Ti-containing gas; an Ar gas supply source 53 for supplying Ar gas as a plasma gas; an H₂ gas supply source 54 for supplying H₂ gas as a reducing gas; an NH₃ gas supply source 55 for supplying NH₃ gas as a nitriding gas; and an N₂ gas supply source 56 for supplying N₂ gas. A ClF₃ gas supply line 57 is connected to the ClF₃ gas supply source 51; a TiCl₄ gas supply line 58 is connected to the TiCl₄ gas supply source 52; an Ar gas supply line 59 is connected to the Ar gas supply source 53; an H₂ gas line 60 is connected to the H₂ gas supply source 54; an NH₃ gas supply line 60a is connected to the NH₃ gas supply source 55; and an N₂ gas supply line 60b is connected to the N₂ gas supply source 56. A mass flow controller 62 and two on-off valves 61 arranged on opposite sides of the mass flow controller 62 are provided in each gas supply line.

The TiCl₄ gas supply line 58 extending from the TiCl₄ gas supply source 52 is connected to the first gas introduction port 41. The ClF₃ gas supply line 57 extending from the ClF₃ gas supply source 51 and Ar gas supply line 59 extending from the Ar gas supply source 53 are connected to the TiCl₄ gas supply line 58. The H₂ gas supply line 60 extending from the H₂ gas supply source 54 is connected to the second gas introduction port 42. The NH₃ gas supply line 60a extending from the NH₃ gas supply source 55 and the N₂ gas supply line 60b extending from the N₂ gas supply source 56 are connected to the H₂ gas supply line 60. Therefore, during film-forming process, TiCl₄ gas and Ar gas are supplied from the TiCl₄ gas supply source 52 and the Ar gas supply source 53, respectively, to the TiCl₄ gas supply line 58, and supplied into the shower head 40 through the first gas introduction port 41. The gases thus supplied are discharged into the chamber 31 through the gas passages 43 and 45 and the discharge holes 47. On the other hand, H₂ gas acting as a reducing gas is supplied from the H₂ gas supply source 54 to the H₂ gas supply line 60, and is introduced into the shower head 40 through the gas introduction port 42, and then is discharged into the chamber 31 through the gas passages 44 and 46 and the discharge holes 48. That is, the shower head 40 is of a post-mix type and hence the TiCl₄ gas and H₂ gas are separately supplied into the chamber 31 in which they are mixed and react with each other. When a nitriding process is performed after a Ti film has been formed, NH₃ gas fed from the NH₃ gas supply source 55, H₂ gas acting as a reducing gas, and Ar gas as a plasma gas are supplied into the chamber 31 through the shower head 40 and the discharge holes 48 to generate plasma and thereby to nitride the Ti film. The valves 61 and the mass flow controllers 62 are controlled by a controller 78.

A transmission path 63 is connected to the shower head 40. The transmission path 63 is connected to a radio-frequency power supply 64 through a matching box 80, allowing radio frequency power to be supplied from the radio frequency power supply 64 to the shower head 40 through the transmission path 63 during the film-forming process. When radio frequency power is supplied from the radio-frequency power supply 64 to the shower head 40, a radio-frequency electric field is produced between the shower head 40 and the electrode 38, and the gas supplied into the chamber 31 is converted into plasma, whereby a Ti film is formed. The radio-frequency power supply 64 is preferably configured to supply a radio frequency power having a frequency of 400 KHz to 60 MHz, preferably 450 KHz.

A circular hole 65 is formed in the center portion of a bottom wall 31b the chamber 31; and an exhaust chamber 66 is formed on the bottom wall 31b such that the exhaust chamber 66 protrudes downward and covers the hole 65. An exhaust pipe 67 is connected to the side of the exhaust chamber 66. An exhaust device 68 is connected to the exhaust pipe 67. The chamber 31 can be evacuated to a predetermined vacuum by operating the exhaust device 68.

Three wafer support pins 69 (only two of which are shown) for supporting and for elevating and lowering the wafer W penetrate through the susceptor 32. The wafer support pins 69 are fixed to a support plate 70, and are raised and lowered by a drive mechanism 71 (an air cylinder, etc.) through the support plate 70 such that the support pins 69 protrude above and retract below the surface of the susceptor 32.

A carrying-in-and-out port 72 and a gate valve G for opening and closing the carrying-in-and-out port 72 are provided on a side wall of the chamber 31. The carrying-in-and-out port 72 is used to transfer a wafer W to and from the wafer transfer chamber 5.

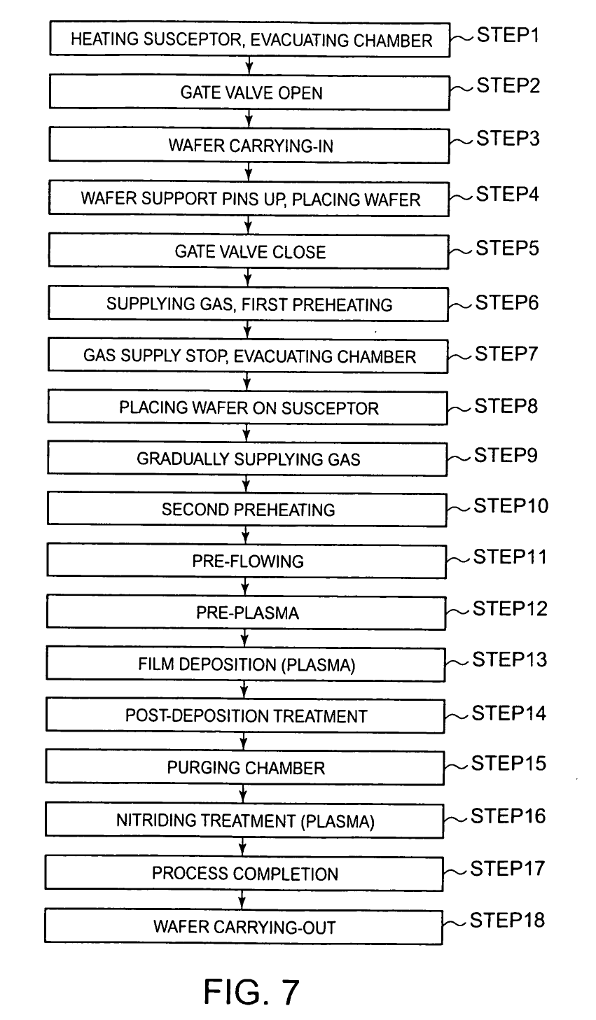

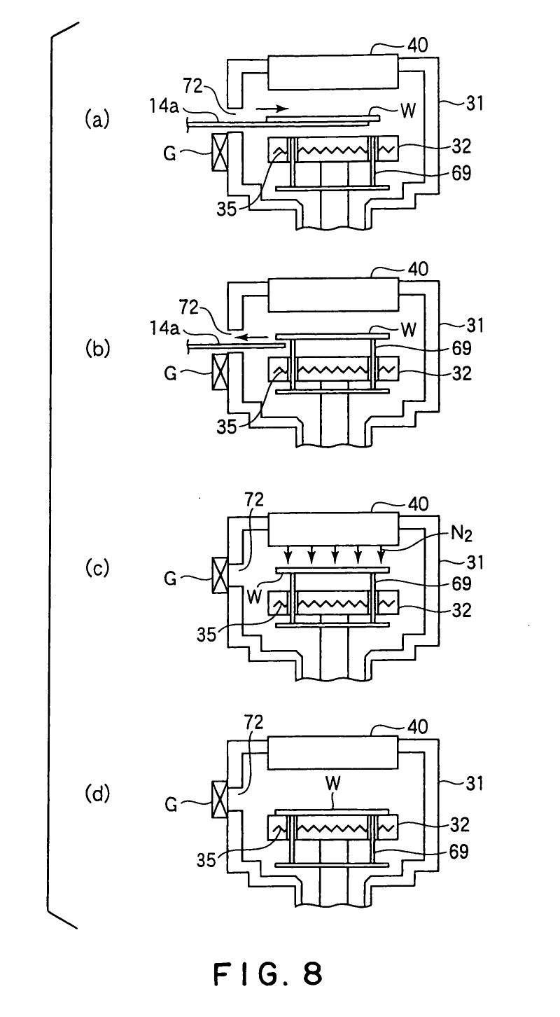

A method for forming a Ti film performed by using the foregoing Ti film-forming apparatus will be described with reference to FIGS. 7 and 8. FIG. 7 is a flowchart illustrating process steps for forming a Ti film in one embodiment; and FIG. 8 shows schematic diagrams showing conditions of the interior of a chamber in each major process step.

First, the susceptor 32 is heated by the heater 35 up to a temperature in a range of about 350° C. to about 700° C., and the chamber 31 is evacuated by the exhaust device 68 to establish a fully-evacuated state (in which there is substantially no gas left in the chamber 31) in the chamber 31(STEP 1). Then, the gate valve 73 is opened (STEP 2), and a wafer W is transferred from the wafer transfer chamber 5 maintained at a vacuum into the chamber 31 through the carrying-in-and-out port 72 by using the blade 14a or 14b of the transfer device 12 (STEP 3), as shown in FIG. 8(a). At the same time, the shower head 40 has been heated by the heater 76 up to 400° C. or higher to prevent the film adhered to the shower head 40 from peeling off.

Then, the wafer W is placed on the wafer support pins 69 projected from the surface of the susceptor 32, as shown in FIG. 8(b) (STEP 4). The gate valve G is closed, while the wafer W is still placed on the wafer support pins 69 (STEP 5), and subsequently Ar gas fed through the TiCl₄ gas supply line 58 is supplied into the chamber 31 through the shower head 40 to perform the first preheating of the wafer W, as shown in FIG. 8(c) (STEP 6). When supplying the Ar gas, N₂ gas is also supplied from the N₂ gas supply source 56 into the chamber 31 at a flow rate substantially the same as that of the Ar gas. The flow rates of the Ar gas and the N₂ gas are gradually increased over a predetermined period of time, e.g., 15 seconds, to gradually increase the pressure in the chamber 31. Each of the flow rates of the Ar gas and the N₂ gas after the completion of the increasing of the flow rates of those gases is preferably in a range of 1 to 10 l/min (liter per minute). The first preheating step may be performed for a period of time in a range of 5 to 30 seconds, preferably about 5 seconds.

After the completion of the first preheating step, the supply of the Ar gas and the N₂ gas is stopped, and the fully-evacuated state is established in the chamber 31 again (STEP 7). Then, the wafer support pins 69 are lowered such that the wafer W is placed on the susceptor 32, as shown FIG. 8(d) (STEP 8). Thereafter, Ar gas and H₂ gas are supplied into the chamber 31 through the TiCI₄ gas supply line 58 and the H₂ gas line 60, respectively, such that their flow rates are gradually increased (ramp-up) to gradually increase the gas pressure in the chamber 31 (STEP 9). After the completion of the increasing of the flow rates of the Ar gas and the N₂ gas, the state at that time is maintained for a predetermined period of time to perform a second preheating step (Step 10). In the second preheating step, each of the flow rates of the Ar gas and the N₂ gas are preferably in a range of 1 to 10 l/min, and the total flow rate is preferably in a range of 1 to 10 l/min. In the second preheating step, the pressure in the chamber 31 is preferably in a range of 100 to 1000 Pa, e.g., 667 Pa. The second preheating step is preferably performed for a period of time in a range of 5 to 30 seconds, e.g., 10 seconds, which period of time is determined taking into account the throughput and the capacity utilization rate of the apparatus. The execution time of each of STEPs 7 to 9 is preferably 10 seconds or less, e.g., 5 seconds.

After the completion of the second preheating step, pre-flowing of TiCl₄ gas at a flow rate in a range of 0.01 to 0.1 l/min by using pre-flow line (not shown) while keeping the flow rates of the Ar gas and the N₂ gas unchanged (STEP 11). During the pre-flowing, the pressure in the chamber 31 is preferably in a range of 100 to 1000 Pa, e.g., 667 Pa; and the pre-flowing is preferably performed for a period of time in a range of 5 to 30 seconds, e.g., 10 seconds. The pre-flow line branches off from the TiCl₄ gas supply line 58 at a point downstream of the mass flow controller 62 but upstream of the junction of the TiCl₄ gas supply line 58 and the Ar gas supply line 59. An on-off valve (not shown) is provided in the pre-flow line. A state in which TiCl₄ gas is fed toward the chamber 31 or a state in which TiCl₄ gas is disposed through the pre-flow line (this is “pre-flowing” state) can selectively be achieved by selectively opening the not shown on-off valve or the on-off valve 61 arranged downstream of the mass flow controller 62 in the TiCl₄ gas line 58. The pre-flowing allows the flow rate of the TiCl₄ gas flowing out of the mass flow controller 62 to be stable at a predetermined value before the supply of the TiCl₄ gas into the chamber 31. As a result, TiCl₄ gas can be supplied into the chamber 31 at a stable flow rate right from the beginning of the supply of the TiCl₄ gas into the chamber 31.

Then, before the film formation, electric power is supplied from the radio-frequency power supply 64 to generate plasma (pre-plasma; STEP 12). In this case, a radio frequency power of 50 to 3000 W, preferably 500 to 2000 W, for example 800 W, having a frequency in a range of 450 KHz to 60 MHz, preferably 450 KHz, is supplied from the radio-frequency power supply 64 to the shower head 40.

The on-off valves are switched such that the TiCl₄ gas which was supplied into the pre-flow line is now supplied into the chamber 31 at the same flow rate at which TiCl₄ gas was supplied into the pre-flow line, while maintaining the flow rates of the Ar gas and H₂ gas, the pressure within the chamber 31, and the radio frequency power at the same levels as those in the previous step, thereby performing the Ti film-forming (film-deposition) step by plasma CVD (STEP 13). The film forming step forms a Ti film having a thickness in a range of 5 to 100 nm. As the film thickness is proportional to the film-forming time, the film-forming time is determined depending on the desired film thickness. That is, the thickness of the film formed can be varied in a range of 5 to 100 nm by adjusting the film-forming time. For example, the film-forming time is set to be 30 seconds to form a film having a thickness of 10 nm. In this case, the wafer W may be heated to a temperature in a range of 350° C. to 800° C., preferably 550° C. to 650° C.

After the completion of the film-forming step, the supply of the TiCl₄ gas is stopped and the supply of electric power from the radio frequency power supply 64 is stopped, while maintaining the supply of the other gases, to perform a post-deposition treatment (post-film-formation treatment) (STEP 14). The post-deposition treatment may be performed for 0.5 to 30 seconds, preferably 1 to 5 seconds, e.g., 2 seconds.

Then, the flow rate of the H₂ gas is reduced while maintaining the flow rate of the Ar gas to purge the chamber 31 (STEP 15). This purging step may be performed for 1 to 30 seconds, preferably 1 to 10 seconds, e.g., example 4 seconds.

Then, the surface of the formed Ti thin film is nitrided (STEP 16). This nitriding step is performed under the following conditions: NH₃ gas is supplied preferably at a flow rate in a range of 0.5 to 5 l/min for about 10 seconds while maintaining the flow rates of the Ar gas and H₂ gas; and thereafter, with keeping the gas supply conditions unchanged, a radio frequency power in a range of 50 to 3000 W, preferably 500 to 1200 W, e.g., 800 W, having a frequency of 450 KHz to 60 MHz, preferably 450 KHz, is supplied from the radio frequency power supply 64 to generate plasma.

After a predetermined period of time has elapsed, the supply of the electric power from the radio frequency power supply 64 is stopped and the gas flow rates are gradually reduced, to complete the film-forming process (STEP 17).

Thereafter, the wafer support pins 69 are raised to lift the wafer W; the gate valve G is opened; the blade 14a or 14b of the transfer device 12 is inserted into the chamber 31; the wafer support pins 69 are lowered to place the wafer W on the blade; and the wafer W is transferred to the transfer chamber 5 (STEP 18).

After a predetermined number of wafers W has been subjected to the foregoing film-forming process, the interior of the chamber 31 is cleaned by supplying CIF3 gas from the CIF3 gas supply source 51.

As mentioned above, the foregoing film-forming method first performs the first preheating step (STEP 6) in which a gas is introduced into the chamber 31 with the wafer W placed on the wafer support pins 69 projected from the susceptor 32, and thus the wafer W is not rapidly heated; and after the wafer W has been heated to some degree, the second preheating step is performed with the wafer W being placed on the susceptor 32. Thus, the thermal stress induced in the wafer W is reduced, preventing or significantly reducing the warpage of the wafer W even if it has a large size such as 300 mm.

After the completion of the first preheating step and before placing the wafer W on the susceptor 32 in STEP 8, the chamber 31 is fully evacuated while the supply of N₂ gas is stopped in STEP 7. This operation prevents slippage of the wafer W on the wafer support pins 69 due to the resistance of the existing gas when the wafer W is lowered. Further, in STEP 9, Ar gas and H₂ gas are supplied into the chamber 31 such that their flow rates are gradually increased (ramp-up) until the gas pressure in the chamber 31 reaches a predetermined level set for the second preheating step (STEP 10). Thus, the wafer W does not subjected to a rapid increase in the gas pressure, more effectively preventing warpage of the wafer W.

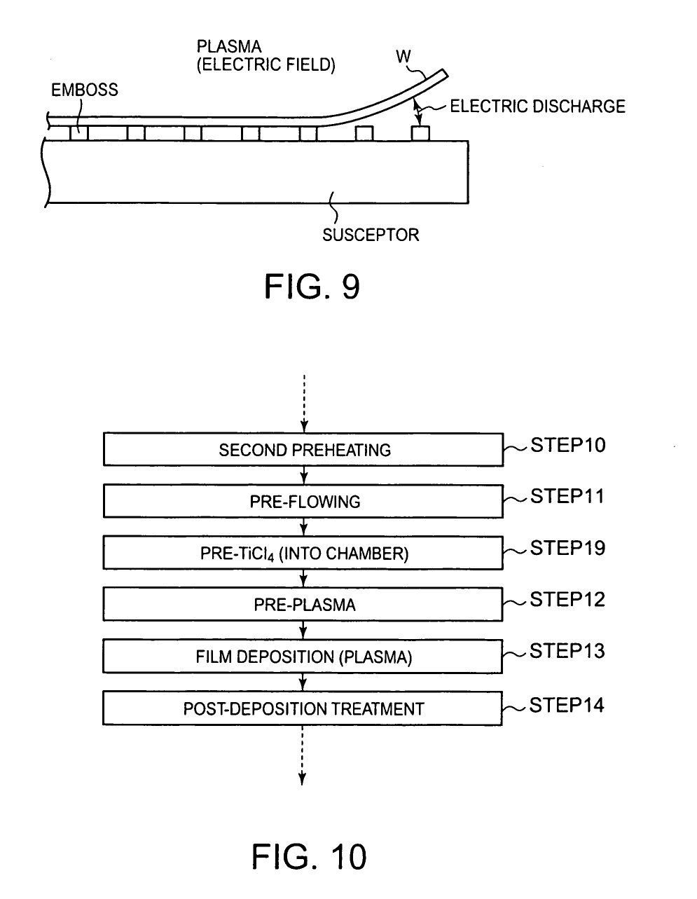

In the conventional art, the peripheral portion of the surface of the susceptor is embossed. Therefore, if the wafer W is warped and hence a gap is formed between the susceptor and the back surface of the wafer as shown in FIG. 9, the electric field concentrates on the embosses and, as a result, an electric discharge starts at the warped portion, leading to an intense local electric discharge. On the other hand, according to the foregoing embodiment, at least the peripheral portion of the top surface of the susceptor 32 is not embossed, and the warpage of the wafer can be significantly suppressed. Thus, it is possible to prevent local electric discharge on the peripheral portion of the susceptor 32.

When the peripheral portion of the susceptor 32 is not embossed, an intense local electric discharge (which could occur when the peripheral portion is embossed) does not occur even if the wafer W is warped. This means that electric discharge on the peripheral portion of the susceptor 32 can be reduced to some degree, even if the foregoing measures for reducing the warpage of the wafer W is omitted. However, according to Paschen's Law, an electric discharge may occur when the amount of warpage of the wafer W has reached a certain level, the film-forming method preferably includes the foregoing steps for reducing the warpage of the wafer W. In order to reliably prevent local electric discharge, it is preferable not to emboss the annular region of the surface of the susceptor 32 extending from the circumference of the circular wafer mounting region (i.e., the seat recess portion 32a) to positions radially inwardly remote from the circumference by 10 mm.

If the warpage of the wafer W is eliminated or significantly reduced by the foregoing steps, an electric discharge is unlikely to occur regardless of whether the peripheral portion of the susceptor is embossed. However, in order to reliably prevent occurrence of an electric discharge, it is preferable to remove any embosses from the peripheral portion of the susceptor, since they may provide the onset point of an electric discharge.

In the pre-plasma step (STEP 12), the electric power supplied from the radio frequency power supply 64 is preferably gradually increased (ramp-up) to a predetermined level (instead of rapidly raising it), in order to reduce the possibility of electric discharge. This operation results in a gradual increase in the magnitude of the electric field, thereby lowering the possibility of electric discharge. In this case, the time it takes to increase the electric power to a predetermined level is preferably in a range of 0.1 to 15 seconds; for example, the electric power may be increased up to 800 W in 1 second.

In order to further reduce the possibility of electric discharge, a step of supplying TiCl₄ gas into the chamber 31 (pre-TiCl₄; STEP 19) may be provided prior to the pre-plasma step (STEP 12), as shown in FIG. 10. If the TiCl₄ gas is supplied into the chamber 31 after the plasma has been generated, the electric potential difference between the plasma and the wafer W may locally increase during the time period from the beginning of the supply of the TiCl₄ gas until the distribution of the TiCl₄ gas has been stabilized. This may result in an electric discharge. On the other hand, if the TiCl₄ gas is supplied into the chamber 31 beforehand and plasma is generated after the distribution of the TiCl₄ gas in the chamber 31 has become uniform, the potential difference distribution between the surface of the wafer and the plasma is narrowed, further reducing the possibility of electric discharge. This process step may be performed in conjunction with the ramp-up of the radio frequency power in the pre-plasma step in order to more effectively reduce the possibility of electric discharge.

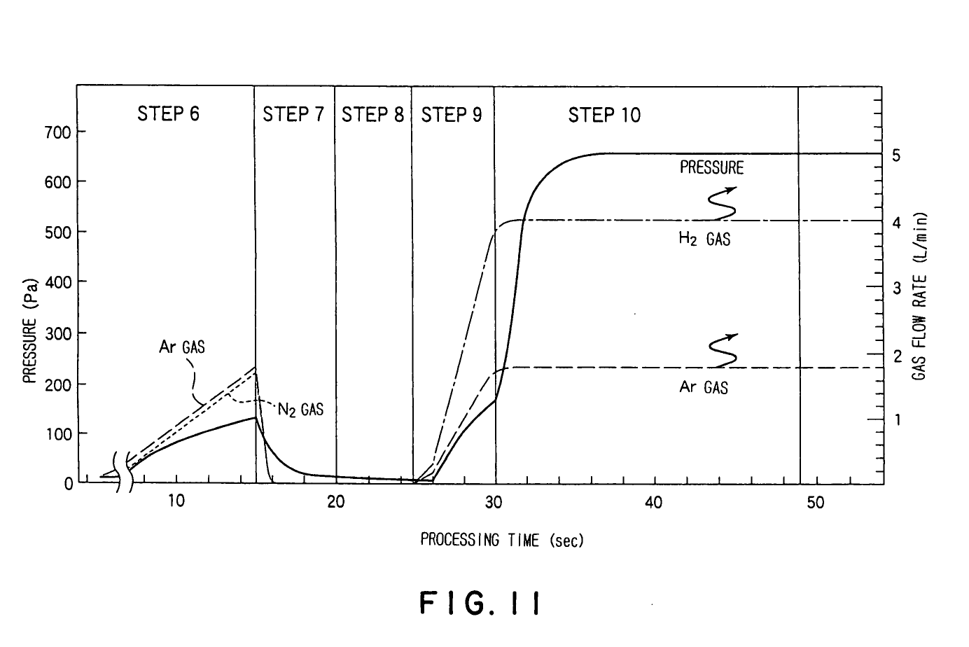

Next, the results of experiments performed to determine the effects of the film-forming method of the present invention will be described. A susceptor having a wafer mounting surface without embosses was used. In this case, the flow rate of each gas and the pressure in the chamber were varied with time as shown in FIG. 11 from the first preheating step (STEP 6) to the second preheating step (STEP 10). Specifically, first, the first preheating step (STEP 6) was performed for 15 seconds while increasing the flow rates of Ar gas and N₂ gas up to 1.8 l/min. Then, after STEP 7 to STEP9 for 5 seconds each have been performed, the second preheating step (STEP 10) was performed for 19 seconds with the H₂ gas flow rate and the Ar gas flow rate being 4 l/min and 1.8 l/min, respectively, and with the pressure being 667 Pa. Then, after the pre-flowing of TiCl₄ gas at a flow rate of 0.012 l/min was performed for 15 seconds (STEP 11), a radio frequency power of 800 W having a frequency of 13.56 MHz was applied to perform a pre-plasma step (STEP 12), and then TiCl4 gas was supplied into the chamber for 30 seconds to form (deposit) a Ti film by plasma CVD (STEP 13). The pressure in the chamber was 667 Pa during the film-deposition. Thus, a Ti film having a thickness of 10 nm was formed on the large-diameter wafer (300 mm). During the above film-forming process, only slight electric discharge was observed between the peripheral portion of the susceptor and the wafer. When the radio frequency power in the pre-plasma step was ramped up (up to 800 W spending 1 second), the electric discharge was further reduced. When the pre-TiCl₄ step (STEP 19) was performed together with the ramping-up of the radio frequency power, no electric discharge was observed.

In a case where the entire surface of the susceptor was embossed and the first preheating step was not performed, an intense local electric discharge was observed between the peripheral portion of the susceptor and the wafer. In a case where the entire surface of the susceptor was embossed, although the first preheating step was performed in an attempt to reduce the warpage of the wafer, significant electric discharge was observed since the wafer was slightly warped.

It should be noted that the present invention is not limited to the embodiment described above, and various modifications may be made thereto. For example, although the film-forming method in the foregoing embodiment forms a Ti film, the present invention is not limited thereto. The present invention can be applied to the formation of any film by plasma CVD. Suitable source gases and other gases may be used depending on the type of film to be formed. Further, although gases are supplied into the chamber during the first and second preheating steps, these preheating steps have a certain degree of effect in reducing the electric discharge even if the gases are not supplied. However, the supply of the gas enhances the effects. Further, if the first preheating step can provide sufficient heating, the second preheating step need not necessarily be performed. Further, the substrate to be processed is not limited to a semiconductor wafer. For example, it may be a substrate for a liquid crystal display (LCD), etc. Further, the substrate may have other layers formed thereon.

The aforementioned series of process steps is automatically carried out under the control of a control computer, i.e., the control unit 19, which controls the whole operations of the film-forming system. All the functional elements of the film forming apparatus are connected to the control unit 19 through a not shown signal lines, to operate according to commands generated by the control unit 19. The term “functional element” means any element which operates to perform a predetermined film-forming process. Concretely, examples of the functional element include: the radio frequency power source 67; the heater power supply 77; the controller 78 for the gas supply mechanism 50; the exhaust device 68; the drive mechanism 71 for the wafer support pins 71; and the wafer transfer devices 12 and 16. The control computer is typically a multi-purpose computer that can achieve any function depending on the software to be executed, but is not limited thereto.

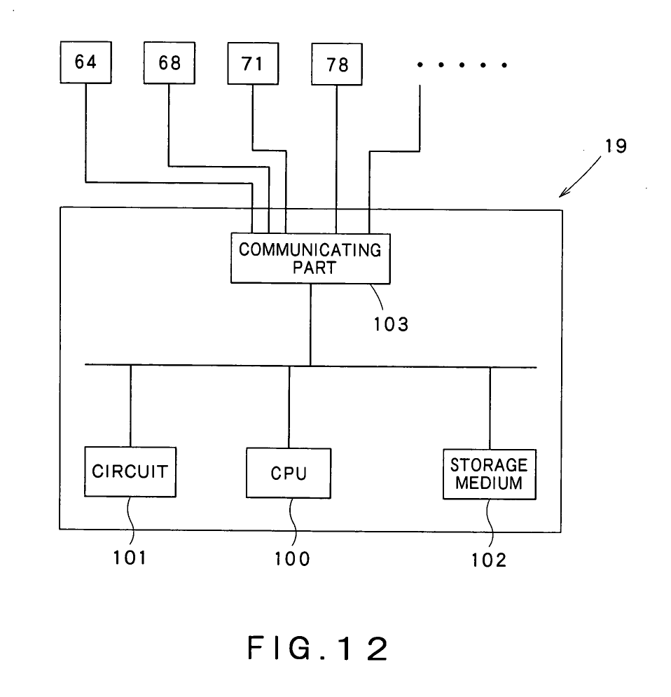

The schematic structure of the control unit 19, or the control computer, is shown in FIG. 12. The control computer includes: a CPU 100; a circuit 101 that supports the CPU 100; a storage medium 102 storing control software including a control program; and a communication part 103 that communicates various signals such as command signals and sensor signals between the functional elements and the computer. Upon execution of the control program, the control computer controls the functional elements of the film-forming system so as to perform the series of process steps shown in FIGS. 7 and 10 based on a predetermined process recipe.

The storage medium 102 may be one fixedly mounted to the control computer, or one detachably loaded into a reader mounted to the control computer and readable by the reader. In the most typical embodiment, the storage medium is a hard disk drive in which the control software is installed by a service person of the manufacturer of the film-forming system. In another embodiment, the storage medium is a removable disk such as a CD-ROM or a DVD-ROM. Such a removable disk is read by an optical reader mounted to the control computer. It should be noted that any storage medium known in the computer art can be used as the storage medium 102. In a factory equipped with plural film-forming systems, the control software may be installed in a managing computer that manages the control computers of the film-forming systems in an integrated fashion. In this case, each of the film-forming system is controlled by the managing computer through a communication line to perform a predetermined process.

1. A chemical vapor deposition method that generates a plasma by using a radio frequency electric field produced in a process chamber, and forms a thin film on a substrate, which is placed on a susceptor and is heated through the susceptor by a heating element arranged in the susceptor, wherein
the substrate is preheated before starting formation of the thin film, with the substrate being held by substrate support pins which are arranged in the susceptor and are in their raised positions.

2. The method according to claim 1, wherein the preheating is performed while supplying a gas into the process chamber.

3. The method according to claim 1, wherein, after the preheating of the substrate is performed with the substrate being supported on the raised substrate support pins, the substrate is further preheated while the substrate support pins are lowered to place the substrate on the susceptor, and thereafter formation of the thin film is started.

4. The method according to claim 4, wherein the preheating performed with the substrate being supported on the raised substrate support pins and the preheating performed with the substrate support pins being lowered and with the substrate being placed on the susceptor are carried out while a gas is supplied into the process chamber.

5. The method according to claim 1, wherein at least a surface of a peripheral portion of a substrate mounting region of the susceptor is formed to be flat, whereby a surface of the substrate opposing the peripheral portion is in face contact with the surface of the peripheral portion when the substrate is placed on the susceptor.

6. A chemical vapor deposition method that generates a plasma by using a radio frequency electric field produced in a process chamber, and forms a thin film on a substrate, which is placed on a susceptor and is heated through the susceptor by a heating element arranged in the susceptor, said method comprising the steps of:
transferring the substrate into the process chamber and raising substrate support pins arranged in the susceptor, thereby supporting the substrate on the substrate support pins;
supplying a gas into the process chamber, which is being evacuated, and heating the susceptor by the heating element, thereby performing first preheating of the substrate while the substrate is being supported on the substrate support pins;
stopping supplying the gas into the process chamber while the process chamber is being evacuated, and lowering the substrate support pins to place the substrate on the susceptor;
supplying a gas into the process chamber while the substrate is placed on the susceptor, thereby performing second preheating of the substrate;
generating a plasma in the process chamber; and
supplying a film-forming gas into the process chamber to form a thin film on the substrate.

7. The method according to claim 6, wherein:
the thin film is a Ti thin film; and
a Ti-containing, film-forming gas and a reducing gas are supplied into the process chamber in the film-forming gas supplying step.

8. The method according to claim 6, further comprising a step of, before the step of performing the second preheating, supplying the gas to be supplied into the process chamber in the step of performing the second preheating such that pressure of the gas in the process chamber gradually increases.

9. The method according to claim 6, wherein the plasma generating step includes gradually increasing intensity of a radio-frequency electric field.

10. The method according to claim 6, further comprising a step of supplying the film-forming gas before the plasma generating step.

11. A plasma chemical vapor deposition apparatus comprising:
a process chamber that accommodates a substrate to be processed;
a susceptor that supports the substrate thereon, the susceptor having a heating element therein;
a gas supply mechanism that supplies at least a film-forming gas into the process chamber; and
plasma generating means for producing a radio-frequency electric field in said process chamber to generate a plasma;
wherein at least a surface of a peripheral portion of a substrate mounting region of the susceptor is formed to be flat, whereby the surface of the peripheral portion is in surface contact with a portion of a surface of the substrate opposing the peripheral portion when the substrate is placed on said susceptor.

12. A storage medium storing a computer program for controlling operations of a chemical vapor deposition apparatus including a process chamber, and a susceptor arranged in the process chamber and having vertically-movable substrate support pins and a heating element, wherein, when a control computer connected to the chemical vapor deposition apparatus executes the control program, the control computer controls the chemical vapor deposition apparatus to perform a film-forming method, said film-forming method comprising the steps of:
supplying a gas into the process chamber, which is being evacuated, and heating the susceptor by the heating element, thereby performing first preheating of the substrate while the substrate being placed on the substrate support pins in their raised position;
stopping supplying the gas into the process chamber while continuing evacuating the process chamber, and lowering the substrate support pins to place the substrate on the susceptor;
supplying a gas into the process chamber while the substrate is placed on the susceptor, thereby performing second preheating of the substrate;
generating a plasma in the process chamber; and
supplying a film-forming gas into the process chamber to form a thin film on the substrate.

13. The storage medium according to claim 12, wherein:
the thin film is a Ti thin film; and
a Ti-containing, film-forming gas and a reducing gas are supplied into the process chamber in the film-forming gas supplying step.

14. The storage medium according to claim 13, wherein the step of generating a plasma in the process chamber and the step of supplying the film-forming gas into the process chamber includes the steps of:
supplying a Ti-containing, film-forming gas and a reducing gas into the process chamber before generating a plasma;
thereafter generating a plasma in the process chamber under a first condition, while continuing the supplying the film-forming gas and the reducing gas; and
thereafter generating a plasma in the process chamber under a second condition, while continuing the supplying the film-forming gas and the reducing gas.

15. The storage medium according to claim 14, wherein the step of generating a plasma under the first condition includes a step of gradually increasing intensity of a radio frequency electric field in the process chamber.

16. The storage medium according to claim 12, further comprising a step of, before the step of performing the second preheating, supplying the gas to be supplied into the process chamber in the step of performing the second preheating such that pressure of the gas in the process chamber gradually increases.
